(19) United States
(12) Patent Application Publication
(10) Pub. No.: US 2026/0076168 A1
(43) Pub. Date: Mar. 12, 2026

(54) SEMICONDUCTOR DEVICES

(71) Applicant: Samsung Electronics Co., Ltd., Suwon-si (KR)

(72) Inventors: Taeha Suh, Suwon-si (KR); Keonhee Park, Suwon-si (KR)

(21) Appl. No.: 19/220,778

(22) Filed: May 28, 2025

(30) Foreign Application Priority Data
Sep. 11, 2024 (KR) 10-2024-0124084

(51) Int. Cl. H01L 23/528; H01L 21/768; H01L 23/00; H01L 25/065; H10B 12/00; H10B 80/00

(52) U.S. Cl. CPC H10W 20/43; H10B 12/315; H10B 12/34; H10B 12/482; H10B 12/50; H10B 12/0335; H10B 12/053; H10B 80/00; H10W 20/069; H10W 80/312; H10W 80/327; H10W 90/00; H10W 90/792

(57) ABSTRACT

A semiconductor device includes: a bit line structure; cell channel structures; word lines; first contact patterns; second contact patterns; an information storage structure; a peripheral transistor; a peripheral conductive interconnection electrically connected to the peripheral transistor; and a contact structure including a first contact plug portion electrically connected to the bit line structure, a second contact plug portion horizontally spaced apart from the first contact plug portion and electrically connected to the peripheral conductive interconnection, and a connection portion extending from the first contact plug portion and the second contact plug portion. The contact structure may include a contact conductive pattern in the connection portion and extending from a portion in the connection portion into the first contact plug portion and the second contact plug portion.

### CROSS-REFERENCE TO RELATED APPLICATION(S)

This application claims the benefit of priority under 35 U.S.C. § 119 to Korean Patent Application No. 10-2024-0124084 filed on Sep. 11, 2024, in the Korean Intellectual Property Office, the disclosure of which is incorporated herein by reference in its entirety.

### BACKGROUND

The present disclosure relates generally to a semiconductor device.

With an increase in demand for high performance, high speed, and/or multifunctionalization of semiconductor devices, the degree of integration of semiconductor devices has increased. In manufacturing a fine pattern semiconductor device corresponding to the trend of high integration of semiconductor devices, it is required to implement patterns with a fine width or a fine separation distance.

### SUMMARY

An aspect of the present disclosure is to provide a semiconductor device including a vertical channel transistor having improved reliability.

However, the object of the present disclosure is not limited to the above-described object, and may be variously extended without departing from the spirit and domain of the present disclosure.

A semiconductor device according to example embodiments of the present disclosure may include: a bit line structure; cell channel structures on the bit line structure and respectively extending in a vertical direction; word lines between the cell channel structures; first contact patterns on the cell channel structures and electrically connected to the cell channel structures; second contact patterns on the first contact patterns; an information storage structure on the second contact patterns; a peripheral transistor including a peripheral gate electrode and a peripheral source/drain; a peripheral conductive interconnection on the peripheral transistor and electrically connected to the peripheral transistor; and a contact structure including a first contact plug portion connected to the bit line structure, a second contact plug portion horizontally spaced apart from the first contact plug portion and electrically connected to the peripheral conductive interconnection, and a connection portion extending from the first contact plug portion and the second contact plug portion, and the contact structure may include a contact conductive pattern in the connection portion and extending from a portion in the connection portion into the first contact plug portion and the second contact plug portion, each of the second contact patterns may include the same material as a material of the contact conductive pattern, and upper surfaces of each of the second contact patterns may be coplanar with an upper surface of the connection portion of the contact structure.

A semiconductor device according to example embodiments of the present disclosure may include: a bit line structure; cell channel structures on the bit line structure and respectively extending in a vertical direction; word lines between the cell channel structures; first contact patterns on the cell channel structures and electrically connected to the cell channel structures; second contact patterns on the first contact patterns; an information storage structure on the second contact patterns; and a first contact structure including a first contact plug connected to the bit line structure, a first connection portion having a width greater than a width of the first contact plug on the first contact plug, and a first contact barrier layer covering a side surface and a lower surface of the first contact plug, and a side surface and a lower surface of the first connection portion, and upper surfaces of each of the second contact patterns may be coplanar with an upper surface of the first contact structure.

A semiconductor device according to example embodiments of the present disclosure may include: a bit line structure; cell channel structures on the bit line structure and respectively extending in a vertical direction; word lines between the cell channel structures; first contact patterns on the cell channel structures and electrically connected to the cell channel structures; second contact patterns including conductive patterns on the first contact patterns and contact pattern barrier layers covering side surfaces and lower surfaces of the conductive patterns; an information storage structure on the second contact patterns; a peripheral transistor including a peripheral gate electrode and a peripheral source/drain; a peripheral conductive interconnection line on the peripheral transistor and electrically connected to the peripheral transistor; and a contact structure including a first contact plug portion connected to the bit line structure, a second contact plug portion electrically connected to the peripheral conductive interconnection line, a connection portion extending from the first contact plug portion and the second contact plug portion, and a contact barrier layer covering a side surface and a lower surface of the first contact plug portion, a side surface and a lower surface of the second contact plug, and a side surface and a lower surface of the connection portion.

According to example embodiments of the present disclosure, contact patterns connected to first electrodes of a data storage structure of a semiconductor device and a contact structure connected to a bit line structure and/or a peripheral circuit device may be formed in the same process, the possibility of damage to the contact patterns that may occur in the process of forming the contact structure may be removed, thereby providing a semiconductor device having improved reliability.

However, the effect of the present disclosure is not limited to the above-described object(s), and may be variously extended without departing from the spirit and domain of the present disclosure.

### BRIEF DESCRIPTION OF DRAWINGS

The above and other aspects, features, and advantages of the present disclosure will be more clearly understood from the following detailed description, taken in conjunction with the accompanying drawings, wherein like reference numerals (when used) indicate corresponding elements throughout the several views, and in which:

FIG. 1 is a schematic perspective view of a semiconductor device according to example embodiments of the present disclosure;

FIG. 2 is a schematic plan view of a semiconductor device according to an example embodiment of the present disclosure;

FIG. 3 is a schematic cross-sectional view taken along line I-I′ of the semiconductor device illustrated in FIG. 2, according to an example embodiment;

FIGS. 4A to 4C are enlarged views according to example embodiments of region A of the semiconductor device of FIG. 3;

FIG. 5 is a schematic cross-sectional view illustrating another example embodiment taken along a line I-I′ of the semiconductor device illustrated in FIG. 2;

FIG. 6 is a schematic cross-sectional view illustrating another embodiment taken along a line I-I′ of the semiconductor device illustrated in FIG. 2; and

FIGS. 7A to 7F are schematic cross-sectional views illustrating an example embodiment of intermediate processes in a method of manufacturing a semiconductor device.

### DETAILED DESCRIPTION

Hereinafter, preferred embodiments of the present disclosure will be described in more detail with reference to the attached drawings. The same reference numerals are used for the same components in the drawings, and duplicate descriptions for the same components may be omitted.

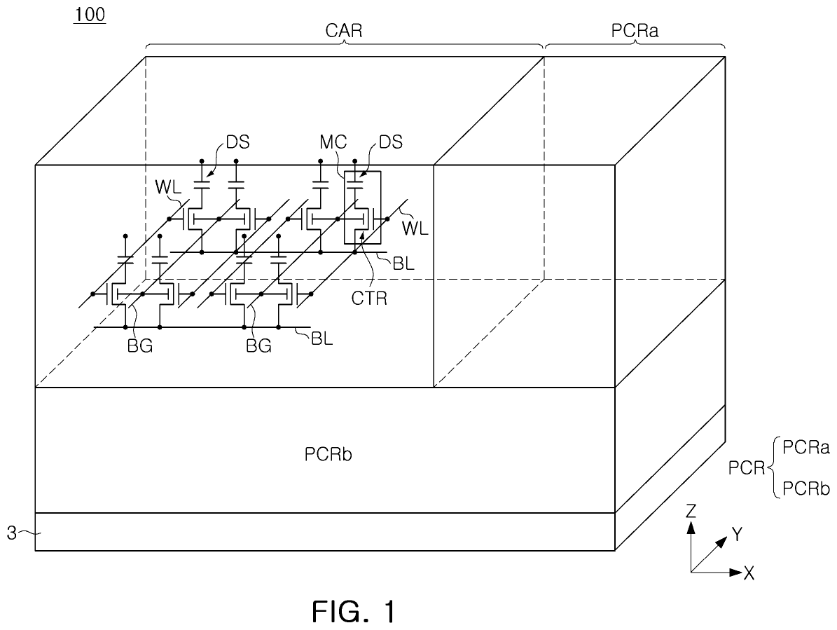

FIG. 1 is a schematic perspective view of a semiconductor device according to example embodiments of the present disclosure.

Referring to FIG. 1, a semiconductor device 100 may include a memory cell array region CAR and a peripheral circuit region PCR. The peripheral circuit region PCR may include a first peripheral circuit region PCRa horizontally spaced apart from the memory cell array region CAR (in an X-direction and/or Y-direction), and a second peripheral circuit region PCRb overlapping the memory cell array region CAR and the first peripheral circuit region PCRa in a vertical direction (Z-direction) perpendicular to a surface (e.g., lower surface) of the semiconductor device 100. As used herein, “an element A overlapping an element B in a direction X” (or similar language) means that there is at least one line that extends in the direction X and intersects both the elements A and B.

The memory cell array region CAR may include a memory cell array. In an example, the memory cell array may include a plurality of bit lines BL, a plurality of word lines WL, a plurality of back gate lines BG, and a plurality of memory cells MC.

Each of the memory cells MC may include a cell transistor CTR and a data storage structure DS. One memory cell MC may be disposed between one word line WL and one bit line BL. The cell array of the semiconductor device 100 may correspond to a memory cell array of a Dynamic Random Access Memory (DRAM) device.

The cell transistor CTR may include a gate, a source, and a drain. The gate may be connected to a word line WL, and the source may be connected to the bit line BL, and the drain may be connected to the data storage structure DS. The data storage structure DS may include a capacitor formed of lower electrodes, an upper electrode on the lower electrodes, and a dielectric layer between the lower electrodes and the upper electrode.

The word lines WL may extend in a second direction (Y-direction) and may be spaced apart from each other in a first direction (X-direction). The first direction (X-direction) and the second direction (Y-direction) may intersect one another and may define a horizontal plane parallel to a surface of the semiconductor device 100 and perpendicular to the vertical direction (Z-direction). The word lines WL may be disposed at the same level, in the vertical direction, and may be connected to different memory cells MC. The bit lines BL may extend in the first direction (X-direction) and may be spaced apart from each other in the second direction (Y-direction).

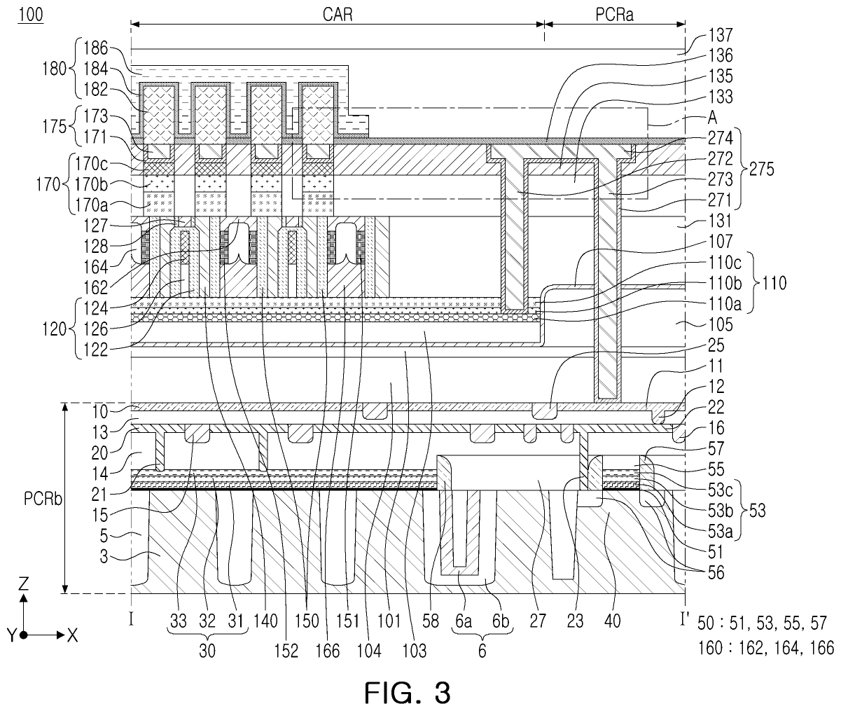

A back gate line BG may be disposed between two adjacent word lines WL. For example, the two word lines WL may share one back gate line BG. A voltage different from that applied to the word line WL may be applied to the back gate line BG. Active patterns (e.g., a channel layer 140 of FIG. 3) which are channels of the cell transistor CTR may be floating bodies, and the back gate line BG may control charges, for example, holes, accumulated in the active patterns, so that a floating body effect may be suppressed or controlled, and a threshold voltage of the cell transistor CTR may be prevented from changing. Accordingly, the back date line BG may improve electrical characteristics of the cell transistor CTR.

The back gate lines BG may be independently and individually controlled by considering the interlayer characteristic distribution of the cell transistors CTR disposed in each layer. At least portions of the back gate lines BG may be electrically connected to each other and controlled together.

The first peripheral circuit region PCRa may be spaced apart from the memory cell array region CAR in a horizontal direction (e.g., in the first direction (X-direction)), and peripheral interconnection lines connected to peripheral transistors disposed in the second peripheral circuit region PCRb may be disposed therein.

The second peripheral circuit region PCRb may disposed below the memory cell array region CAR and the first peripheral circuit region PCRa, thus overlapping the memory cell array region CAR and the first peripheral circuit region PCRa in the vertical direction (Z-direction). The second peripheral circuit region PCRb may include peripheral circuit elements including peripheral transistors. For example, logic elements such as an inverter circuit, a NAND gate circuit, a NOR gate circuit, an AND gate circuit, an OR gate circuit, an XOR gate circuit, an XNOR gate circuit, a NOT gate circuit, an antifuse, or the like, may be disposed in the second peripheral circuit region PCRb. Additionally, the second peripheral circuit region PCRb may include sub-word line drivers electrically connected to the word lines WL and sense amplifiers electrically connected to the bit lines BL. However, the present disclosure is not limited thereto. For example, at least portions of the logic elements, the sub-word line drivers, and the sense amplifiers may be disposed in the first peripheral circuit region PCRa. In another example embodiment, the semiconductor element 100 may be formed only of the memory cell array region CAR and the first peripheral circuit region PCRa horizontally spaced apart from the memory cell array region CAR.

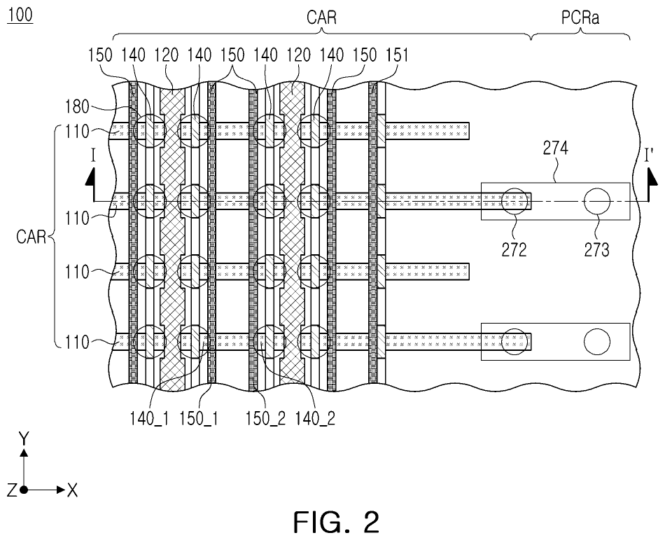

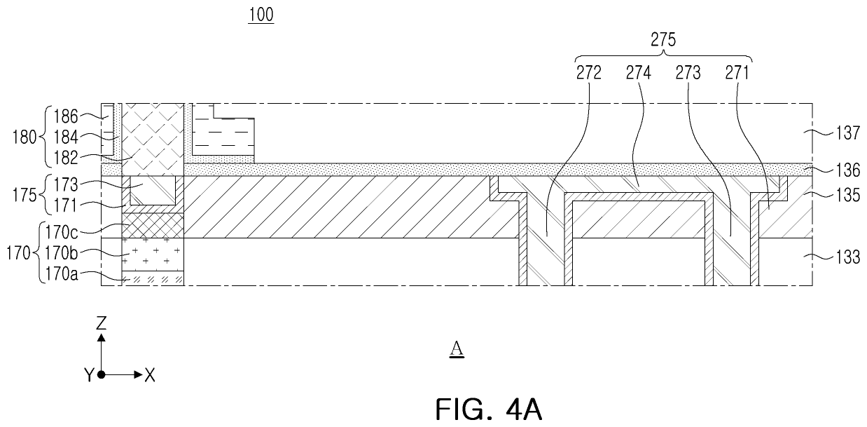

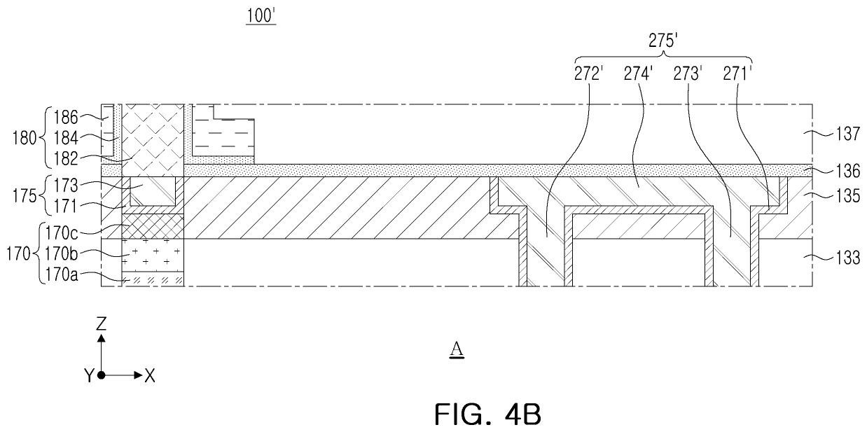

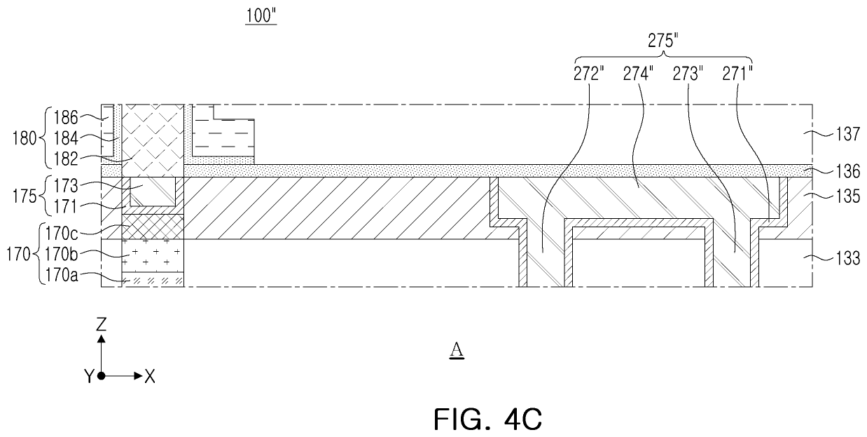

FIG. 2 is a schematic plan view of a semiconductor device according to an example embodiment of the present disclosure. FIG. 3 is a schematic cross-sectional view taken along line I-I′ of the semiconductor device illustrated in FIG. 2 according to an example embodiment. FIG. 4A is an enlarged view illustrating region A of the semiconductor device of FIG. 3 according to example embodiments.

Referring to FIGS. 2 and 3, the semiconductor device 100 may include a second peripheral circuit region PCRb, a memory cell array region CAR disposed on the second peripheral circuit region PCRb, and a first peripheral circuit region PCRa disposed on the second peripheral circuit region PCRb and connected to the second peripheral circuit region PCRb.

The second peripheral circuit region PCRb may include a substrate 3 including a peripheral active region 40, a peripheral circuit element 50 on the substrate 3, a first peripheral interconnection structure 30, second peripheral interconnection structures 20 and 21 connected to the first peripheral interconnection structure 30, third peripheral interconnection structures 22 and 23 connected to the peripheral circuit element 50, and fourth peripheral interconnection structures 11 and 12 connected to the third peripheral interconnection structures 22 and 23.

The substrate 3 may include a semiconductor material, for example, a group IV semiconductor, a group III-V compound semiconductor, or a group II-VI compound semiconductor. For example, the group IV semiconductor may include silicon, germanium, or silicon-germanium. The substrate 3 may further include impurities. The substrate 3 may be a silicon substrate, a silicon-on-insulator (SOI) substrate, a germanium substrate, a germanium-on-insulator (GOI) substrate, a silicon-germanium substrate, or a substrate including an epitaxial layer.

The second peripheral circuit region PCRb may further include a first peripheral device isolating layer 5 defining the peripheral active regions 40 in the substrate 3. The first peripheral device isolating layer 5 may extend downwardly from an upper surface of the substrate 3. The first peripheral device isolating layer 5 may define the peripheral active region 40. The first peripheral device isolating layer 5 may surround the peripheral active regions 40 and separate the peripheral active regions 40 from each other. The term “surround” (or “surrounds,” or like terms), as may be used herein, is intended to broadly refer to an element, structure or layer that extends around, envelops, encircles, or encloses another element, structure or layer on all sides, although breaks or gaps may also be present. Thus, for example, a material layer having voids or gaps therein may still “surround” another layer which it encircles. The first peripheral device isolating layer 5 may include an insulating material. For example, the first peripheral element isolating layer 5 may include silicon oxide, silicon nitride, silicon oxynitride, or combinations thereof, and may be formed of a single layer or a plurality of layers.

The first peripheral interconnection structure 30 may be disposed on the substrate 3. The first peripheral interconnection structure 30 may include a first peripheral conductive pattern 31, a second peripheral conductive pattern 32 on the first peripheral conductive pattern 32, and a third peripheral conductive pattern 33 on the second peripheral conductive pattern 32. The first peripheral conductive pattern 31 may include at least one of doped polysilicon, TiN, TiAl, TiAlC, TiAlN, TaN, TaAlC, or TaAlN. The second peripheral conductive pattern 32 may include a metal nitride such as titanium nitride (TiN) or a silicide material such as titanium silicide (TiSi), and the third peripheral conductive pattern 33 may include a metallic material such as titanium (Ti), tantalum (Ta), tungsten (W), and aluminum (Al). However, the material of layers included in the first peripheral interconnection structure 30, the type of layers, the number of layers, and the thickness of the layers, in vertical direction (Z-direction), may be variously changed according to example embodiments.

The peripheral circuit element 50 may include a planar transistor. The peripheral circuit element 50 may be disposed on the substrate 3 and spaced apart from the first peripheral interconnection structure 30 in the first direction (X-direction). The peripheral circuit element 50 may include a peripheral circuit gate dielectric layer 51, a peripheral gate spacer 57, peripheral gate electrodes 53, and a peripheral gate capping layer 55. Peripheral source/drain regions 56 may be disposed in the substrate 3 on both sides of the peripheral gate electrodes 53.

The peripheral gate dielectric layer 51 may be disposed on a channel region formed between the peripheral source/drain regions 56. The peripheral gate dielectric layer 51 may include at least one of silicon oxide or a high dielectric constant (high-κ) dielectric material.

The peripheral gate electrodes 53 may be disposed on the peripheral gate dielectric layer 51. The peripheral gate electrodes 53 may include a first peripheral gate electrode 53a, a second peripheral gate electrode 53b, and a third peripheral gate electrode 53c, which are stacked in the vertical direction (Z-direction). The first peripheral gate electrode 53a may include at least one conductive layer. For example, the first peripheral gate electrode 53a may include at least one of doped polysilicon, titanium nitride (TiN), titanium aluminide (TiAl), titanium aluminum carbide (TiAlC), titanium aluminum nitride (TiAlN), tantalum nitride (TaN), tantalum aluminum carbide (TaAlC), or tantalum aluminum nitride (TaAlN). The second peripheral gate electrode 53b may include a titanium silicon nitride (TiSiN) layer. The third peripheral gate electrode 53c may include a W (tungsten) layer. In an example, the peripheral gate electrodes 53 may be formed in the same process as the first peripheral interconnection structure 30, but the present disclosure is not limited thereto. The peripheral gate capping layer 55 may be disposed on the peripheral gate electrodes 53. The peripheral gate capping layer 55 may include an insulating material, for example, silicon nitride.

The peripheral gate spacer 57 may cover the side surfaces of the peripheral gate electrodes 53 and the peripheral gate capping layer 55. The term “cover” (or “covering,” or like terms), as may be used herein, is intended to broadly refer to an element, structure or layer that is on or over another element, structure or layer, either directly or with one or more other intervening elements, structures or layers therebetween. The peripheral gate spacer 57 may include at least one of silicon oxide or a low dielectric constant (low-κ) dielectric material.

The peripheral circuit element 50 is illustrated as being disposed on the second peripheral circuit region PCRb overlapping the first peripheral circuit region PCRa in the vertical direction (Z-direction), but the present disclosure is not limited thereto. For example, the peripheral circuit element 50 may be disposed on a second peripheral circuit region PCRb overlapping the memory cell array region CAR.

The second peripheral circuit region PCRb may further include an insulating spacer 58 and a first isolation insulating pattern 27 disposed between the first peripheral interconnection structure 30 and the peripheral circuit element 50 on the substrate 3. The first isolation insulating pattern 27 may be disposed on the peripheral active region 40 and the second peripheral device isolating layer 6. The second peripheral device isolating layer 6 may be disposed in the substrate 3 overlapping a space between the peripheral circuit element 50 and the first peripheral interconnection structure 30, and may extend downwardly from the upper surface of the substrate 3. The second peripheral device isolating layer 6 may include a first insulating pattern 6a and a second insulating pattern 6b covering a side surface and a bottom surface of the first insulating pattern 6a.

The semiconductor device 100 may further include a first interlayer insulating layer 14, a second interlayer insulating layer 13, a third interlayer insulating layer 104, a fourth interlayer insulating layer 101, a fifth interlayer insulating layer 103, and sixth, seventh and eighth interlayer insulating layers 131, 133 and 135. The interlayer insulating layers in this document may include an insulating material, for example, silicon oxide or silicon nitride.

The insulating spacer 58 may cover a partial side surface of the first interlayer insulating layer 14 on the first peripheral interconnection structure 30 while covering ends of the first peripheral interconnection structure 30. The insulating spacer 58 may be disposed between the first peripheral interconnection structure 30 and the first separation insulating pattern 27 and between the first interlayer insulating layer 14 and the first separation insulating pattern 27.

The first separation insulating pattern 27 may surround a side surface of the insulating spacer 58 and a side surface of the peripheral circuit element 50. An upper surface of the first separation insulating pattern 27 may be coplanar with an upper surface of the peripheral gate capping layer 55. The first separation insulating pattern 27 may include silicon oxide.

The first interlayer insulating layer 14 may be disposed on the first peripheral interconnection structure 30, the insulating spacer 58, the first separation insulating pattern 27, and the peripheral circuit element 50.

The second peripheral interconnection structures 20 and 21 connected to the first peripheral interconnection structure 30 and the third peripheral interconnection structures 22 and 23 connected to the peripheral circuit element 50 may be disposed on the first interlayer insulating layer 14.

The second peripheral interconnection structures 20 and 21 may include second peripheral interconnection lines 20 on the first interlayer insulating layer 14 and second peripheral vias 21 penetrating through (i.e., extending in) the first interlayer insulating layer 14 to connect the second peripheral interconnection lines 20 and the first peripheral interconnection structure 30. The term “connect” (or “connecting,” or like terms, such as “contact” or “contacting”), as may be used herein, is intended to refer to a physical and/or electrical connection between two or more elements, and may include other intervening elements. As used herein, the term “and/or” includes any and all combinations of one or more of the associated listed items. In an example, the third peripheral interconnection structures 22 and 23 may include third peripheral interconnection lines 22 on the first interlayer insulating layer 14 and third peripheral vias 23 penetrating through the first interlayer insulating layer 14 and the first separation insulating pattern 27 to connect the third peripheral interconnection lines 22 and the peripheral source/drain regions 56 of the peripheral circuit elements 50. The second peripheral interconnection line 20 and the third peripheral interconnection line 22 may be disposed at the same level in the vertical direction (Z-direction), relative to an upper surface of the substrate 3 as a reference layer. The second peripheral interconnection structures 20 and 21 may be disposed on the second peripheral circuit region PCRb overlapping the first peripheral interconnection structure 30 in the vertical direction. The third peripheral interconnection structures 22 and 23 may be disposed on the second peripheral circuit region PCRb overlapping the peripheral circuit element 50 in the vertical direction.

Second separation insulating patterns 15 disposed between the second peripheral interconnection lines 20 and third separation insulating patterns 16 disposed between the third peripheral interconnection lines 22 may be further included on the second peripheral circuit region PCRb of the semiconductor element 100. The second separation insulating patterns 15 may spatially separate the second peripheral interconnection lines 20. The third separation insulating patterns 16 may spatially separate the third peripheral interconnection lines 22.

A second interlayer insulating layer 13 may be disposed on the second peripheral interconnection structures 20 and 21 and the third peripheral interconnection structures 22 and 23.

The fourth peripheral interconnection structures 11 and 12 and a peripheral auxiliary interconnection line 10 connected to the third peripheral interconnection structures 22 and 23 may be disposed on the second interlayer insulating layer 13. In an example, the fourth peripheral interconnection structures 11 and 12 may include the fourth peripheral interconnection line 11 disposed on the second interlayer insulating layer 13 and the second interlayer insulating layer 12 penetrating the second interlayer insulating layer 13 and connecting the fourth peripheral interconnection line 11 and the third peripheral interconnection structures 22 and 23. In an example, the peripheral auxiliary interconnection line 10 and the fourth peripheral interconnection line 11 may be disposed at the same level in the vertical direction, relative to the upper surface of the substrate 3. A fourth separation insulating pattern 25 disposed between the peripheral auxiliary interconnection line 10 and the fourth peripheral interconnection line 22 may be further included on the second peripheral circuit region PCRb of the semiconductor device 100. The fourth separation insulating pattern 25 may spatially separate the fourth peripheral interconnection line 22 and the peripheral auxiliary interconnection line 10. In an example, the fourth peripheral interconnection structures 11 and 12 may be disposed on the second peripheral sacrificial region PCRb overlapping the first peripheral sacrificial region PCRa. In this document, the fourth peripheral interconnection line 11 may be referred to as a ‘peripheral conductive interconnection line.’

The third interlayer insulating layer 104 and the fourth interlayer insulating layer 101 may be sequentially disposed on the peripheral auxiliary interconnection line 10 and the fourth peripheral interconnection structures 11 and 12 over the memory cell array region CAR and the first peripheral circuit region PCRa on the second peripheral circuit region PCRb.

An insulating liner 107 and a fifth separation insulating pattern 105 may be disposed on the fourth interlayer insulating layer 101. The insulating liner 107 may be disposed on the fourth interlayer insulating layer 101 overlapping the memory cell array region CAR, and may thus extend to a side surface and an upper surface of the fifth separation insulating pattern 105. The insulating liner 107 may cover the side surface and upper surface of the fifth separation insulating pattern 105. The fifth separation insulating pattern 105 may be disposed on the fourth interlayer insulating layer 101 overlapping the first peripheral circuit region PCRa.

The fifth interlayer insulating layer 103 and a bit line structure 110 may be disposed sequentially on the insulating liner 107 overlapping the memory cell array region CAR. The fifth separation insulating pattern 105 may be disposed adjacently to one side of the fifth interlayer insulating layer 103 and the bit line structure 110. One side of the fifth interlayer insulating layer 103 and the bit line structure 110 may be in contact with the insulating liner 107.

The memory cell array region CAR of the semiconductor device 100 may include the bit line structure 110, a back gate structure 120, a channel layer 140, word lines 150, first contact patterns 170, second contact patterns 175 on the first contact patterns 170, and an information storage structure 180.

The semiconductor device 100 may include a vertical channel transistor including the channel layer 140, the bit line structure 110 electrically connected to the channel layer 140, and the word lines 150 disposed on at least one side of the channel layer 140.

The bit line structure 110 may extend on the fifth interlayer insulating layer 103 in the first direction (X-direction). In an example, the bit line structure 110 may be embedded on the fifth interlayer insulating layer 103. The bit line structure 110 may be electrically connected to the channel layer 140.

The bit line structure 110 may be plural, and a plurality of bit line structures 110 may be spaced apart from each other in the second direction (Y-direction) and may extend in parallel with one another.

The bit line structure 110 may include doped polysilicon, a metal, a conductive metal nitride, a metal-semiconductor compound, a conductive metal oxide, a conductive graphene, a carbon nanotube, or combinations thereof. For example, at least one of the bit line structures 110 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, carbon nanotubes, or combinations thereof. In an example embodiment, the bit line structure 110 may include a first conductive pattern 110a, a second conductive pattern 110b, and a third conductive pattern 110c, which are sequentially stacked on a fifth interlayer insulating layer 103. The first conductive pattern 110a may include a metallic material such as titanium (Ti), tantalum (Ta), tungsten (W), and aluminum (Al), the second conductive pattern 110b may include a metal nitride such as titanium nitride (TiN) or a silicide material such as titanium silicide (TiSi), and the third conductive pattern 110c may include a semiconductor material such as polycrystalline silicon. The third conductive pattern 110c may be a layer doped with impurities. However, according to example embodiments, the material of layers included in the bit line structure 110, the number of layers, and the thickness of the layers may be variously changed. The bit line structure 110 may correspond to the bit line BL of FIG. 1.

The back gate structure 120 may intersect the bit line structure 110. For example, a plurality of back gate structures 120 may extend in the second direction (Y-direction) and may be spaced apart from each other in the first direction (X-direction).

Each of the back gate structures 120 may include a back gate dielectric layer 122, a back gate electrode 124, and a back gate capping layer 126. The back gate electrodes 124 may extend in the second direction (Y-direction) and may be spaced apart from each other in the first direction (X-direction). The back gate electrode 124 may serve to remove charges trapped in the channel layer 140. The channel layer 140 may be a floating body, and the back gate electrode 124 may be a structure for supplementing the floating channel layer 140 to prevent or minimize performance degradation of the semiconductor device 100 due to the floating body effect of the channel layer 140.

The back gate electrode 124 may include doped polysilicon, a metal, a conductive metal nitride, a metal-semiconductor compound, a conductive metal oxide, graphene, carbon nanotubes, or combinations thereof. For example, the back gate electrode 124 may be formed of doped polysilicon, Al, Cu, Ti, Ta, Ru, W, Mo, Pt, Ni, Co, TiN, TaN, WN, NbN, TiAl, TiAlN, TiAlC, TaAlC, TiSi, TiSiN, TaSi, TaSiN, RuTiN, NiSi, CoSi, IrOx, RuOx, graphene, carbon nanotubes, or combinations thereof, but the present disclosure is not limited thereto. The back gate electrode 124 may be formed of a single layer or multiple layers of the materials described above.

The back gate dielectric layers 122 may extend in the second direction (Y-direction) along both side surfaces and an upper surface of the back gate electrodes 124. A vertical length of the back gate dielectric layer 122 may be greater than a vertical length of the back gate electrode 124. For example, an upper surface of the back gate dielectric layer 122 may be disposed on a level higher than a level of the upper surface of the back gate electrode 124 in the vertical direction (Z-direction), and a lower surface of the back gate dielectric layer 122 may be disposed on a level lower than a level of a lower surface of the back gate electrode 124 in the vertical direction (Z-direction), relative to the upper surface of the substrate 3 as a reference.

The back gate capping layer 126 may be disposed between the back gate dielectric layers 122 below the back gate electrode 124. The lower surface of the back gate dielectric layers 122 and lower surfaces of the back gate capping layers 126 may be in contact with the third conductive pattern 110c. The back gate dielectric layer 122 and the back gate capping layer 126 may include at least one of silicon oxide or high-κ dielectric. The back gate electrode 124 may correspond to the back gate line BG of FIG. 1.

An upper back gate capping layer 127 and a capping liner 128 may be disposed on the back gate electrodes 124. Upper surfaces of the upper back gate capping layer 127 and the capping liner 128 may be coplanar with an upper surface of the channel layer 140. The upper back gate capping layer 127 and the capping liner 128 may include silicon nitride.

Each of the channel layers 140 may be disposed on the bit line structure 110 and may extend in the vertical direction (Z-direction). The channel layers 140 may be disposed on both sides of the back gate structure 120. The channel layers 140 may be spaced apart from each other in the first direction (X-direction) and the second direction (Y-direction). The upper surface of the channel layer 140 may be coplanar with the upper surface of the upper back gate capping layer 127 and the upper surface of the capping liner 128. A lower surface of the channel layer 140 may be in contact with a lower surface of the third conductive pattern 110c.

Each of the channel layers 140 may include a first source/drain region in contact with the bit line structure 110 and a second source/drain region connected to the first contact patterns 170. In an example, the first and second source/drain regions may have an N-type conductivity type.

The channel layers 140 may include a single crystal semiconductor material. The single crystal semiconductor material may include a group IV semiconductor, a group III-V compound semiconductor, or a group II-VI compound semiconductor, and may be, for example, a single crystal semiconductor including at least one of silicon, silicon carbide, germanium, or silicon-germanium. However, the present disclosure is not limited thereto, and the channel layers 140 may include at least one of a polycrystalline semiconductor material layer, an oxide semiconductor material layer such as Indium Gallium Zinc Oxide (IGZO), or a two-dimensional material layer such as MoS_{2.}

The oxide semiconductor material layer may be indium gallium zinc oxide (IGZO). However, this example embodiment is not limited thereto. For example, the oxide semiconductor material layer may include at least one of Indium Tungsten Oxide (IWO), Indium Tin Gallium Oxide (ITGO), Indium Aluminum Zinc Oxide (IAGO), Indium Gallium Oxide (IGO), Indium Tin Zinc Oxide (ITZO), Zinc Tin Oxide (ZTO), Indium Zinc Oxide (IZO), ZnO, Indium Gallium Silicon Oxide (IGSO), Indium Oxide (InO), Tin oxide (SnO), Titanium Oxide (TiO), Zinc Oxynitride (ZnON), Magnesium Zinc Oxide (MgZnO), Indium Zinc Oxide (InZnO), Indium Gallium Zinc Oxide (InGaZnO), Zirconium Indium Zinc Oxide (ZrInZnO), Hafnium Indium Zinc Oxide (HfInZnO), Tin Indium Zinc Oxide (SnInZnO), Aluminum Tin Indium Zinc Oxide (AlSnInZnO), Silicon Indium Zinc Oxide (SiInZnO), Zinc Tin Oxide (ZnSnO), Aluminum Zinc Tin Oxide (AlZnSnO), Gallium Zinc Tin Oxide (GaZnSnO), Zirconium Zinc Tin Oxide (ZrZnSnO), or Indium Gallium Silicon Oxide (InGaSiO).

The two-dimensional material layer may include at least one of a Transition Metal Dichalcogenide (TMD) material layer, a black phosphorous material layer, or a hexagonal Boron-Nitride (hBN) material layer, which may have semiconductor properties. For example, the two-dimensional material layer may include at least one of BiOSe, Crl, WSe₂, MoS₂, TaS, WS, SnSe, ReS, β-SnTe, MnO, AsS, P(black), InSe, h-BN, GaSe, GaN, SrTiO, MXene, or Janus 2D materials, which may form a two-dimensional material.

The word lines 150 may be disposed on the bit line structure 110 and may be arranged on both side surfaces of the back gate structures 120. The word lines 150 may be spaced apart from each other in the first direction (X-direction) and may extend in the second direction (Y-direction). The word lines 150 may surround at least a portion of each of the channel layers 140, and each of the channel layers 140 may be disposed between the back gate structure 120 and the word line 150. The word lines 150 may include a first word line 150_1 and a second word line 150_2 disposed between two adjacent back gate structures 120. The channel layer 140 may include a first channel layer 140_1 and a second channel layer 140_2 disposed between two adjacent back gate structures 120. The first word line 150_1 and the second word line 150_2 may be disposed between the first channel layer 140_1 and the second channel layer 140_2. The word line 150 may correspond to the word line WL of FIG. 1.

The word line 150 may include doped polysilicon, a metal, a conductive metal nitride, a metal-semiconductor compound, a conductive metal oxide, conductive graphene, carbon nanotubes, or combinations thereof. For example, the word line 150 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, graphene, carbon nanotubes, or combinations thereof, but the present disclosure is not limited to. The word line 150 may include a single layer or multiple layers of the materials described above.

The semiconductor device 100 may further include a dummy word line 151 disposed in an outermost edge in the memory cell array region CAR. The dummy word line 151 may include the same material as a material of the word line 150.

The semiconductor device 100 may further include a gate dielectric layer 152 and an insulating structure 160 in the memory cell array region CAR.

The gate dielectric layer 152 may be disposed between the word line 150 and the channel layer 140. A lower surface of the gate dielectric layer 152 may be in contact with the third conductive pattern 110c, and an upper surface of the gate dielectric layer 152 may be in contact with the first contact patterns 170. The upper surface of the gate dielectric layer 152 may be coplanar with the upper surface of the channel layer 140, relative to the upper surface of the substrate 3. In an example, each of the gate dielectric layers 152 may be a tunnel dielectric layer that does not include an information storage layer. For example, each of the gate dielectric layers 152 may include at least one of silicon oxide and a high-κ dielectric. The high-κ dielectric may include a metal oxide or a metal oxide nitride. For example, the high dielectric may be formed of HfO₂, HfSiO, HfSiON, HfTaO, HfTiO, HfZrO, ZrO₂, Al₂O₃, or combinations thereof, but the present disclosure is not limited thereto. Each of the gate dielectric layers 152 may be formed of a single layer or multiple layers of the materials described above. In another example, each of the gate dielectric layers 152 may include an information storage layer and a dielectric layer. For example, each of the gate dielectric layers 152 may include a ferroelectric layer that may have polarization characteristics according to an electric field and may have remnant polarization due to a dipole even in the absence of an external electric field. Data may be recorded using the polarization state in the ferroelectric layer. Accordingly, each of the gate dielectric layers 152 may include a ferroelectric layer that may be referred to as an information storage layer. The ferroelectric layer, which may be the information storage layer, may include a Hf-based compound, a Zr-based compound, and/or a Hf—Zr-based compound. For example, the Hf-based compound may be a HfO-based ferroelectric material, the Zr-based compound may include a ZrO-based ferroelectric material, and the Hf—Zr-based compound may include a HZO (hafnium zirconium oxide)-based ferroelectric material. The ferroelectric layer, which may be the information storage layer, may include a ferroelectric material doped with impurities, for example, at least one of C, Si, Mg, Al, Y, N, Ge, and Sn, Gd, La, Sc, and Sr. For example, the ferroelectric layer, which may be the information storage layer, may be a material in which at least one of HfO₂, ZrO₂, and HZrO is doped with at least one of C, Si, Mg, Al, Y, N, Ge, Sn, Gd, La, Sc, or Sr. In the gate dielectric layers 152, the information storage layer is not limited to the above-described material type and may include a material capable of storing information.

In an example, the insulating structure 160 may be disposed between two back gate structures 120. The insulating structure 160 may include an upper gate capping layer 162 covering upper portions of the word lines 150, a lower gate capping layer 166 covering lower portions of the word lines 150, and an intermediate gate capping layer 164 disposed between the upper gate capping layer 162 and the lower gate capping layer 166.

The upper gate capping layer 162 and the lower gate capping layer 166 may overlap the word lines 150 in the vertical direction (Z-direction). The upper gate capping layer 162 may cover an upper surface of the first word line 150_1 and an upper surface of the second word line 150_2, and may have an inverted U-shape in a cross-sectional view. The lower gate capping layer 166 may cover a lower surface of the first word line 150_1 and a lower surface of the second word line 150_2. The intermediate gate capping layer 164 may be disposed between the upper gate capping layer 162 and the lower gate capping layer 166, and may extend between the first word line 150_1 and the second word line 150_2. The insulating structure 160 may include silicon oxide, silicon nitride, silicon oxynitride, silicon carbonitride, a low-κ dielectric, or combinations thereof. In an example, the upper gate capping layer 162 and the lower gate capping layer 166 may include silicon nitride, and the intermediate gate capping layer 164 may include silicon oxide. In another example, the intermediate gate capping layer 164 may include a low-κ dielectric material having a lower dielectric constant than silicon oxide.

The sixth interlayer insulating layer 131 may be disposed on the bit line structure 110 extending in the first direction (X-direction), adjacent to the first peripheral circuit region PCRa. The sixth interlayer insulating layer 131 may be disposed at an outermost edge in the memory cell array region CAR, and may surround a channel layer 140 adjacent to a dummy word line 151. An upper surface of the sixth interlayer insulating layer 131 may be coplanar with the upper surfaces of the channel layers 140, the upper surfaces of the gate dielectric layers 152, upper surfaces of the upper gate capping layers 162, the upper surface of the upper back gate capping layer 127, and the upper surface of the capping liner 128, relative to the upper surface of the substrate 3.

The first contact patterns 170 may be disposed on the channel layers 140 and may be electrically connected to the channel layers 140. Lower surface of the first contact patterns 170 may also be in contact with the upper surfaces of the gate dielectric layers 152 and the upper surface of the upper gate capping layer 162. The first contact patterns 170 may include a conductive material, for example, doped single-crystal silicon, doped polycrystalline silicon, a metal, a conductive metal nitride, a metal-semiconductor compound, a conductive metal oxide, conductive graphene, carbon nanotubes, or combinations thereof. In an example embodiment, the first contact patterns 170 may include first to third contact layers 170a, 170b and 170c, which are sequentially stacked in the vertical direction (Z-direction). For example, the first contact layer 170a may include undoped polycrystalline silicon, the second contact layer 170b may include doped polycrystalline silicon, and the third contact layer 170c may include a silicide material. However, according to example embodiments, the number of layers and the type of material of the first contact patterns 170 may be variously changed.

The seventh interlayer insulating layer 133 surrounding at least one side of the first contact patterns 170 may be disposed on the upper gate capping layers 162, the upper back gate capping layer 127, and the capping liner 128. In an example, the seventh interlayer insulating layer 133 may surround the first contact layer 170a and the second contact layer 170b. However, the present disclosure is not limited thereto, and the seventh interlayer insulating layer 133 may surround portions of the first contact layer 170a, the second contact layer 170b and the third contact layer 170c.

The second contact patterns 175 may be disposed on the first contact patterns 170. The second contact patterns 175 may overlap the first contact patterns 170 in a vertical direction (Z-direction). In an example, each of the second contact patterns 175 may include a first conductive pattern 173 and a first contact pattern barrier layer 171 covering a side surface and a lower surface of the first conductive pattern 173. The first conductive pattern 173 may include a metallic material such as, for example, tungsten, aluminum, or copper. The first contact pattern barrier layer 171 may include a metal nitride such as, for example, titanium nitride, tantalum nitride, or tungsten nitride. The eighth interlayer insulating layer 135 surrounding the second contact patterns 175 may be disposed on the seventh interlayer insulating layer 133. The eighth interlayer insulating layer 135 may surround side surfaces of the second contact patterns 175 and a side surface of the third contact layer 170c. An upper surface of the eighth interlayer insulating layer 135 may be coplanar with upper surfaces of the second contact patterns 175, relative to the upper surface of the substrate 3.

The first contact patterns 170 and the second contact patterns 175 on the first contact patterns 170 may electrically connect the channel layers 140 and the information storage structure 180.

The semiconductor device 100 may further include a contact structure 275 connected to the bit line structure 110 and the fourth peripheral interconnection structures 11 and 12. The contact structure 275 may include a first contact plug portion 272 extending in the vertical direction and connected to the bit line structure 110, a second contact plug portion 273 extending in the vertical direction and connected to the fourth peripheral interconnection structures 11 and 12, a connection portion 274 extending from the first contact plug portion 272 and the second contact plug portion 273 to connect the first and second contact plug portions 272 and 273, and a contact barrier layer 271 disposed on side surfaces and lower surfaces of the first and second contact plug portions 272 and 273 and side surfaces and lower surfaces of the connection portion 274. The contact barrier layer 271 may have a uniform thickness according to surface profiles of the first and second contact plug portions 272 and 273 and the connection portion 274.

The first contact plug portion 272 may be connected to the bit line structure 110 by extending in the vertical direction through the sixth, seventh and eighth interlayer insulating layers 131, 133 and 135. The second contact plug portion 273 may be connected to the fourth peripheral interconnection structures 11 and 12 by extending in the vertical direction through the sixth, seventh and eighth interlayer insulating layers 131, 133 and 135, the insulating liner 107, the fifth separation insulating pattern 105, the third interlayer insulating layer 104, and the fourth interlayer insulating layer 101. The second contact plug portion 273 may be connected to the fourth peripheral interconnection structures 11 and 12 and may be connected to the peripheral circuit element 50. The connection portion 274 may extend from the side surface of the first contact plug portion 272 and the side surface of the second contact plug portion 273. The contact barrier layer 271 may cover the lower surface and the side surface of the first contact plug portion 272 and the lower surface and the side surface of the second contact plug portion 273, and may extend from the side surfaces of the first and second contact plug portions 272 and 273 to cover the lower surface and the side surface of the connection portion 274. The connection portion 274 may overlap the first and second contact plug portions 272 and 273 in the vertical direction (Z-direction).

An upper surface of the second contact patterns 175 may be coplanar with an upper surface of the contact structure 275 and the upper surface of the eighth interlayer insulating layer 135, relative to the upper surface of the substrate 3. In an example, the upper surface of the second contact patterns 175 may be coplanar with an upper surface of the connection portion 274 of the contact structure 275.

The eighth interlayer insulating layer 135 may surround the side surfaces of the second contact patterns 175, the side surface of the connection portion 274 of the contact structure 275, upper end portions of the first contact plug portions 272, and upper end portions of the second contact plug portions 273. A lower surface of the eighth interlayer insulating layer 135 may be disposed on a level lower than a level of lower surfaces of the second contact patterns 175 and the lower surface of the connection portion 274 of the contact structure 275, relative to the upper surface of the substrate 3.

The lower surface of the first contact plug portion 272 may be arranged at a higher level than the lower surface of the second contact plug portion 273, relative to the upper surface of the substrate 3. In an example, a length from the lower surface of the first contact plug portion 272 to the lower surface of the connection portion 274 may be smaller than a length from the lower surface of the second contact plug portion 273 to the lower surface of the connection portion 274. In an example, the bit line structure 110 connected to the first contact plug portion 272 may be disposed on a level higher than a level of the fourth peripheral interconnection structures 11 and 12 connected to the second contact plug portion 273.

In an example embodiment, the first contact plug portion 272, the second contact plug portion 273 and the connection portion 274 may be formed integrally with each other. The contact structure 275 may be disposed in the connection portion 274 and may include contact conductive patterns extending from a portion disposed in the connection portion 274 into the first contact plug portion 272 and the second contact plug portion 273. The contact conductive patterns may include a metallic material such as, for example, tungsten, aluminum, or copper. In an example, the contact conductive pattern included in the first contact plug portion 272, the second contact plug portion 273 and the connection portion 274 may include the same material as a material of the first conductive pattern 173 of the second contact pattern 175. In an example, the contact barrier layer 271 may include a metal nitride such as titanium nitride, tantalum nitride, or tungsten nitride. The contact barrier layer 271 may include the same material as a material of the first contact pattern barrier layer 171 of the second contact pattern 175.

Referring to FIGS. 3 and 4A, the lower surface of the second contact patterns 175 may be disposed at a lower level than a level of the lower surface of the connection portion 274 of the contact structure 275, relative to the upper surface of the substrate 3. A length of each of the second contact patterns 175 in the vertical direction (Z-direction) may be longer than a length of the connection portion 274 of the contact structure 275 in the vertical direction (Z-direction). A length of each of the second contact patterns 175 in the vertical direction may be a length from a lower surface of the first contact pattern barrier layer 171 to an upper surface of the first conductive pattern 173. A length of the connection portion 274 of the contact structure 275 in the vertical direction may be a length from the lower surface to the upper surface of the connection portion 274.

A first etching stop layer 136 may be disposed on the eighth interlayer insulating layer 135 and the contact structure 275. The first etching stop layer 136 may be in contact with the upper surface of the eighth interlayer insulating layer 135 and the upper surface of the contact structure 275. The first etch stop layer 136 may include at least one of silicon nitride (SiN), silicon oxynitride (SiON), silicon carbonitride (SiCN), or silicon boron nitride (SiBN).

The information storage structure 180 may include first electrodes 182 electrically connected to the second contact patterns 175, a second electrode 186 covering the first electrodes 182, and a dielectric layer 184 between the first electrodes 182 and the second electrode 186. The information storage structure 180 may completely or partially overlap the second contact patterns 175 in the vertical direction (Z-direction). The first electrodes 182 may be disposed on the second contact patterns 175 by penetrating through the first etch stop layer 136. The information storage structure 180 may correspond to the information storage structure DS of FIG. 1.

The information storage structure 180 may be a capacitor for storing information in a DRAM. For example, the dielectric layer 184 of the information storage structures 180 may be a capacitor dielectric layer of the DRAM, and the dielectric layer 184 may include a high-κ dielectric, silicon oxide, silicon nitride, silicon oxynitride, or combinations thereof.

The information storage structures 180 may be structures for storing information of the DRAM and other memories. For example, the dielectric layer 184 of the information storage structures 180 may be a capacitor dielectric layer of a ferroelectric memory (FeRAM). In this case, the dielectric layer 184 may be a ferroelectric layer that may record data using a polarization state. The ferroelectric layer may also, in another example embodiment, include a lower dielectric layer including at least one of silicon oxide or a high-κ dielectric, and a ferroelectric layer disposed on the lower dielectric layer.

An upper insulating film 137 may be disposed on the information storage structure 180 and the first etching stop layer 136. The upper insulating film 137 may cover the second electrode 186 of the information storage structure 180 and the first etching stop layer 136. The upper insulating film 137 may include silicon oxide or silicon nitride.

FIGS. 4B and 4C are enlarged views according to example embodiments of region A of the semiconductor device of FIG. 3.

Referring to FIG. 4B, the remaining components except a contact structure 275′ may be identical to or may correspond to the components illustrated in FIG. 3. The contact structure 275′ of a semiconductor device 100′ may include a first contact plug portion 272′, a second contact plug portion 273', a connection portion 274′ extending in the first direction (X-direction) from the first contact plug portion 272′ and the second contact plug portion 273′, and a contact barrier layer 271′ covering a side surface and a lower surface of the first contact plug portion 272′, a side surface and a lower surface of the second contact plug portion 273′, and a side surface and a lower surface of the connection portion 274′.

The lower surface of the second contact patterns 175 may be disposed at substantially the same level as the lower surface of the connection portion 274′ of the contact structure 275′, relative to the upper surface of the substrate 3; that is, lower surface of the second contact patterns 175 may be coplanar with the lower surface of the connection portion 274′ of the contact structure 275′. In an example, a length of the second contact patterns 175 in the vertical direction (Z-direction) may be substantially the same as a length of the connection portion 274′ of the contact structure 275′ in the vertical direction (Z-direction).

Referring to FIG. 4C, the remaining components except a contact structure 275″ may be identical to or may correspond to the components illustrated in FIG. 3. The contact structure 275″ of a semiconductor device 100″ may include a first contact plug portion 272″, a second contact plug portion 273″, a connection portion 274″ extending from the first contact plug portion 272″ and the second contact plug portion 273″, and a contact barrier layer 271″ covering a side surface and a lower surface of the first contact plug portion 272″, a side surface and a lower surface of the second contact plug portion 273″, and a side surface and a lower surface of the connection portion 274″.

A lower surface of the second contact patterns 175 may be on a level higher than the lower surface of the connection portion 274″ of the contact structure 275″, relative to the upper surface of the substrate 3. In an example, a length of the second contact patterns 175 in the vertical direction (Z-direction) may be smaller than a length of the connection portion 274″ of the contact structure 275″ in the vertical direction (Z-direction).

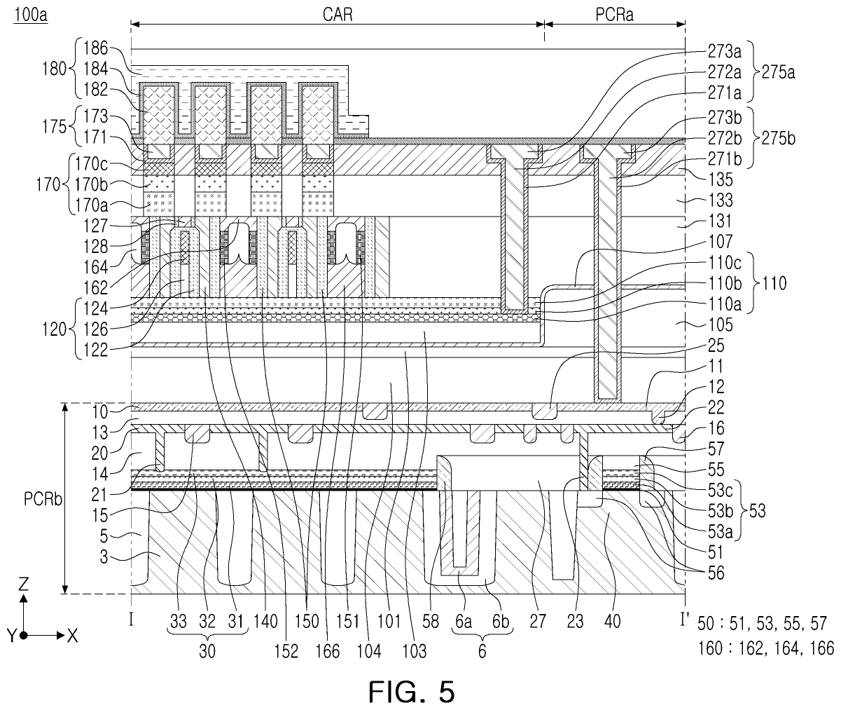

FIG. 5 is a schematic cross-sectional view illustrating another example embodiment taken along a line I-I′ of the semiconductor device illustrated in FIG. 2.

Referring to FIG. 5, the remaining components except the first and second contact structures 275a and 275b may be identical to or may correspond to the components illustrated in FIG. 3.

A semiconductor element 100a may include a first contact structure 275a connected to the bit line structure 110 and a second contact structure 275b spaced apart from the first contact structure 275a in the first direction (X-direction) and connected to the fourth peripheral interconnection structures 11 and 12.

The first contact structure 275a may include a first contact plug 272a connected to the bit line structure 110, a first connection portion 273a disposed on the first contact plug 272a, and a first contact barrier layer 271a covering a lower surface and a side surface of the first contact plug 272a and a lower surface and a side surface of the first connection portion 273a extending from the side surface of the first contact plug 272a. In an example, the first contact structure 275a may include a first contact conductive pattern disposed in the first connection portion 273a and extending from a portion disposed in the first connection portion 273a into the first contact plug 272a.

The second contact structure 275b may include a second contact plug 272b connected to the fourth peripheral interconnection structures 11 and 12, a second connection portion 273b disposed on the second contact plug 272b, and a second contact barrier layer 271b covering a lower surface and a side surface of the second contact plug 272b and a lower surface and a side surface of the second connection portion 273b extending from the side surface of the second contact plug 272b. In an example, the second contact structure 275b may include a second contact conductive pattern disposed in the second connection portion 273b and extending from a portion disposed in the second connection portion 273b into the second contact plug 272b.

The upper surface of the second contact patterns 175, an upper surface of the first contact structure 275a, and an upper surface of the second contact structure 275b may be coplanar with each other, relative to the upper surface of the substrate 3.

The first conductive pattern 173 of the second contact patterns 175, the first contact conductive pattern of the first contact structure 275a, and the second contact conductive pattern of the second contact structure 275b may include the same material. For example, the first conductive pattern 173 of the second contact patterns 175, the first contact conductive pattern of the first contact structure 275a, and the second contact conductive pattern of the second contact structure 275b may include tungsten.

The first contact pattern barrier layer 171 of the second contact patterns 175, the first contact barrier layer 271a of the first contact structure 275a, and the second contact barrier layer 271b of the second contact structure 275b may include the same material.

A width of each of the first connection portion 273a and the second connection portion 273b in the first direction (X-direction) may be greater than a width of the first contact plug 272a and the second contact plug 272b in the first direction (X-direction).

A length of the first connection portion 273a of the first contact structure 275a and the second connection portion 273b of the second contact structure 275b in the vertical direction (Z-direction) may be less than a length of the second contact patterns 175 in the vertical direction (Z-direction). However, the present disclosure is not limited thereto, and the length of the first connection portion 273a of the first contact structure 275a and the second connection portion 273b of the second contact structure 275b in the vertical direction (Z-direction) may be substantially identical to or greater than the length of the second contact patterns 175 in the vertical direction (Z-direction).

The length of the first connection portion 273a of the first contact structure 275a in the vertical direction (Z-direction) may be substantially identical to the length of the second connection portion 273b of the second contact structure 275b in the vertical direction (Z-direction). However, the present disclosure is not limited thereto, and the length of the first connection portion 273a of the first contact structure 275a in the vertical direction (Z-direction) may be different from the length of the second connection portion 273b of the second contact structure 275b in the vertical direction (Z-direction).

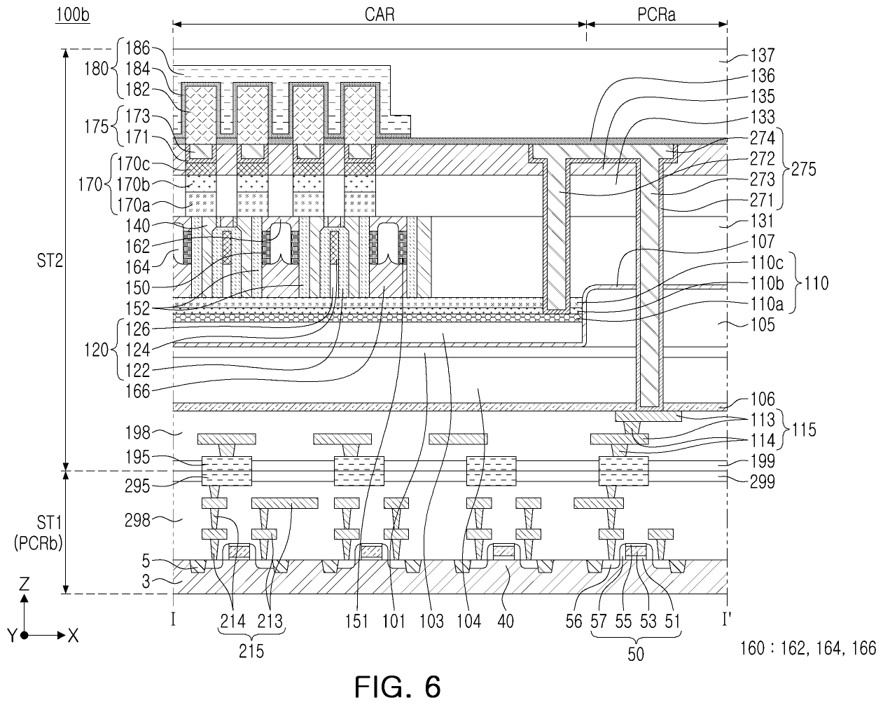

FIG. 6 is a schematic cross-sectional view illustrating another embodiment taken along a line I-I′ of the semiconductor device illustrated in FIG. 2.

Referring to FIG. 6, the remaining components except a second etching stop layer 106, an upper interconnection structure 115, an upper interlayer insulating layer 198, an upper bonding insulating layer 199, upper bonding pads 195, a lower interconnection structure 215, a lower interlayer insulating layer 298, a lower bonding insulating layer 299, and lower bonding pads 295, which are disposed below the third interlayer insulating layer 104 may be identical to or may correspond to the components illustrated in FIG. 3.

Referring to FIG. 6, a semiconductor device 100b may include a first structure ST1 including a second peripheral circuit region PCRb and a second structure ST2 including a first peripheral circuit region PCRa and a memory cell array region CAR.

The first structure ST1 may include peripheral circuit elements 50 on a substrate 3, a lower interlayer insulating layer 298 on the substrate 3 and the peripheral circuit elements 50, an upper interconnection structure 115, a lower bonding insulating layer 299, and lower bonding pads 295. The second structure ST2 may include a second etch stop layer 106, an upper interconnection structure 115, an upper interlayer insulating layer 198, an upper bonding insulating layer 199, and upper bonding pads 195, which are disposed in a lower portion of a third interlayer insulating layer 104.

The lower interlayer insulating layer 298 may be disposed on the peripheral circuit elements 50 on the substrate 3. The lower interlayer insulating layer 298 may include a plurality of insulating layers formed in different process operations. The lower interlayer insulating layer 298 may include an insulating material.

The lower interconnection structure 215 may include lower interconnection lines 213 and lower contact plugs 214. The lower interconnection lines 213 and lower contact plugs 214 may be electrically connected to the peripheral circuit elements 50 and the peripheral source/drain regions 56. The lower interconnection lines 213 may have a line shape that extends in the horizontal plane (X-direction and/or Y-direction), and the lower contact plugs 214 may have a cylindrical shape extending in the vertical direction (Z-direction). An electrical signal may be applied to the peripheral circuit elements 50 by the lower interconnection structure 215. In an unillustrated region, the lower contact plug 214 may also be connected to the peripheral gate electrodes 53. The lower interconnection structure 215 may include a conductive material, for example, tungsten (W), copper (Cu), or aluminum (Al), and each of the components may further include a diffusion barrier.

The lower bonding pads 295 may at least partially overlap corresponding upper bonding pads 195 in the vertical direction, and the lower bonding pads 295 may be electrically connected to the corresponding upper bonding pads 195. The lower bonding pads 295 may be connected to the lower interconnection structure 215. However, the present disclosure is not limited thereto, and portions of the lower bonding pads 295 may not be connected to the lower interconnection structure 215 and may be disposed only for bonding.

The lower bonding pads 295 may include a conductive material, for example, copper (Cu). The lower bonding insulating layer 299 may be disposed around the lower bonding pads 295. The lower bonding insulating layer 299 may also function as a diffusion barrier layer of the lower bonding pads 295. For example, the lower bonding insulating layer 299 may include at least one of SiN, SiON, SiCN, SiOC, SiOCN, or SiO.

The second etch stop layer 106 may be disposed in the lower portion the third interlayer insulating layer 104. The second contact plug portion 273 of the contact structure 275 may be connected to the upper interconnection structure 115 by penetrating through the second etch stop layer 106. In an example, the second contact plug portion 273 of the contact structure 275 may be connected to upper interconnection lines 113.

The upper interconnection structure 115 may be disposed in the third interlayer insulating layer 104. The upper interconnection structure 115 may include the upper interconnection lines 113 and an upper contact plug 114. The upper interconnection lines 113 may have a line shape, and the upper contact plug 114 may have a cylindrical shape.

The upper bonding pads 195 may be connected to the upper interconnection structure 115. However, the present disclosure is not limited thereto, and portions of the upper bonding pads 195 may not be connected to the upper interconnection structure 115 and may be disposed only for bonding.

The upper bonding pads 195 may include a conductive material, for example, copper (Cu). The upper bonding insulating layer 199 may be disposed around the upper bonding pads 195. The upper bonding insulating layer 199 may also function as a diffusion barrier layer of the upper bonding pads 195.

The first structure ST1 and the second structure ST2 may be bonded and connected to each other by applying pressure to the upper bonding insulating layer 199, the lower bonding insulating layer 299, the upper bonding pads 195 and the lower bonding pads 295.

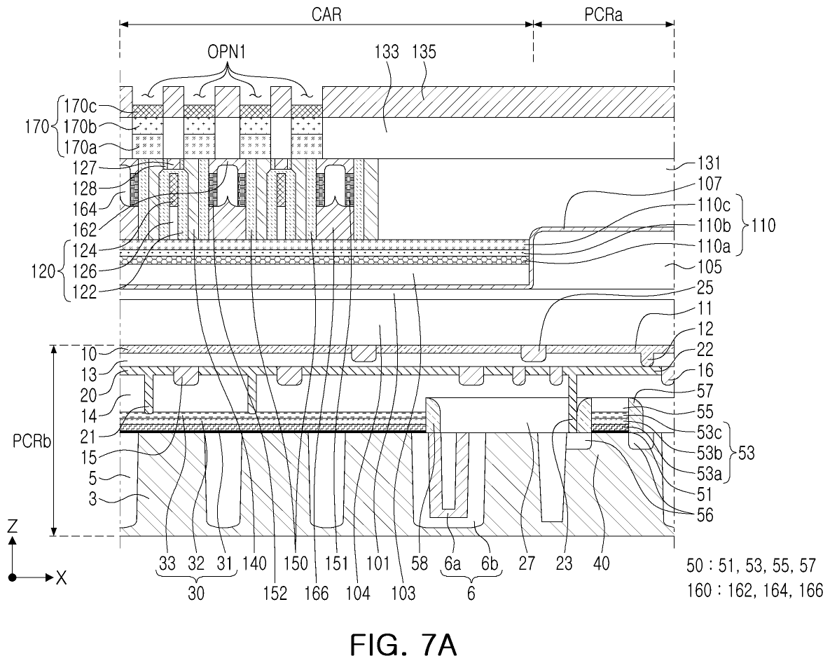

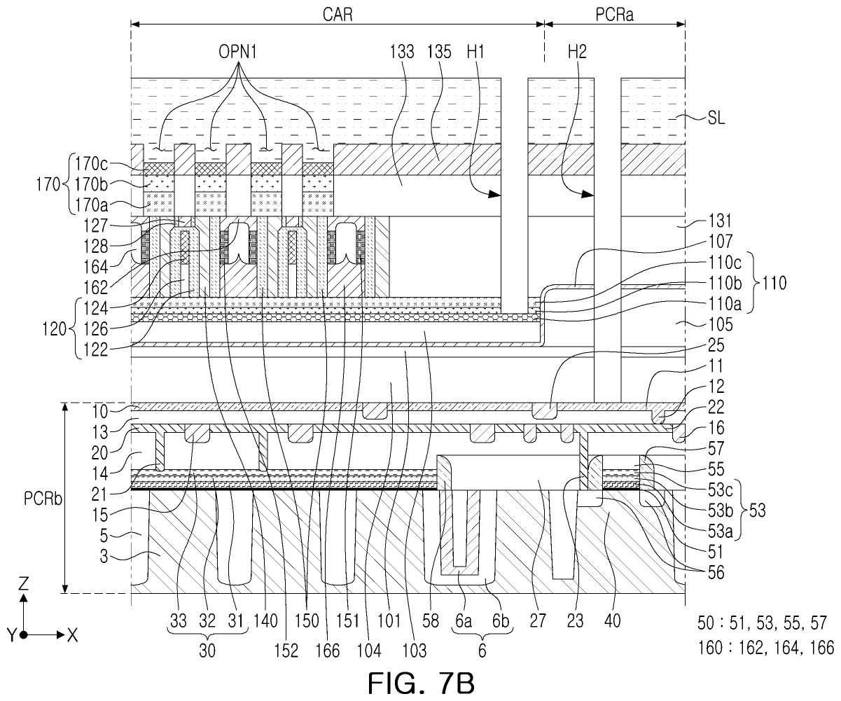

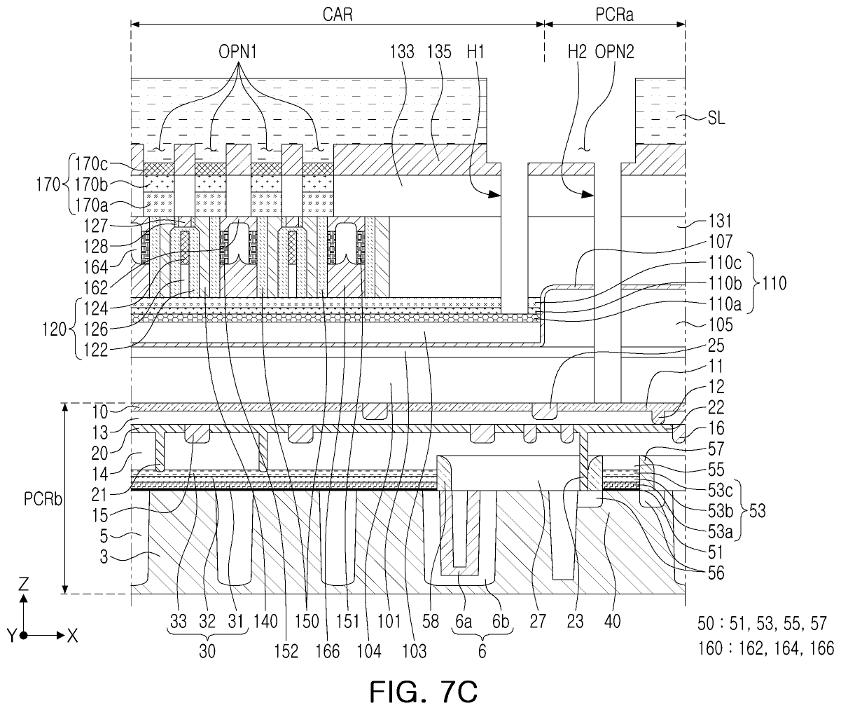

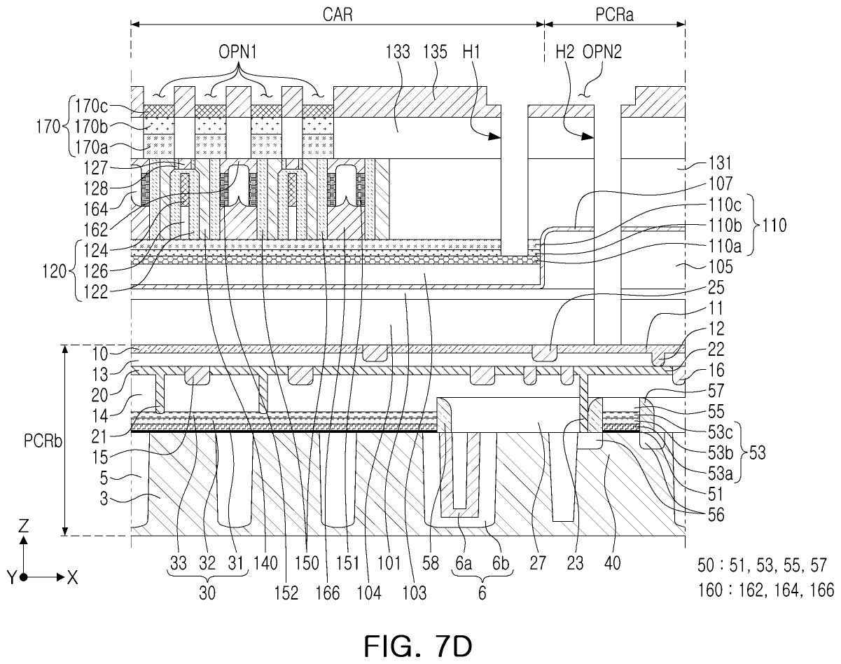

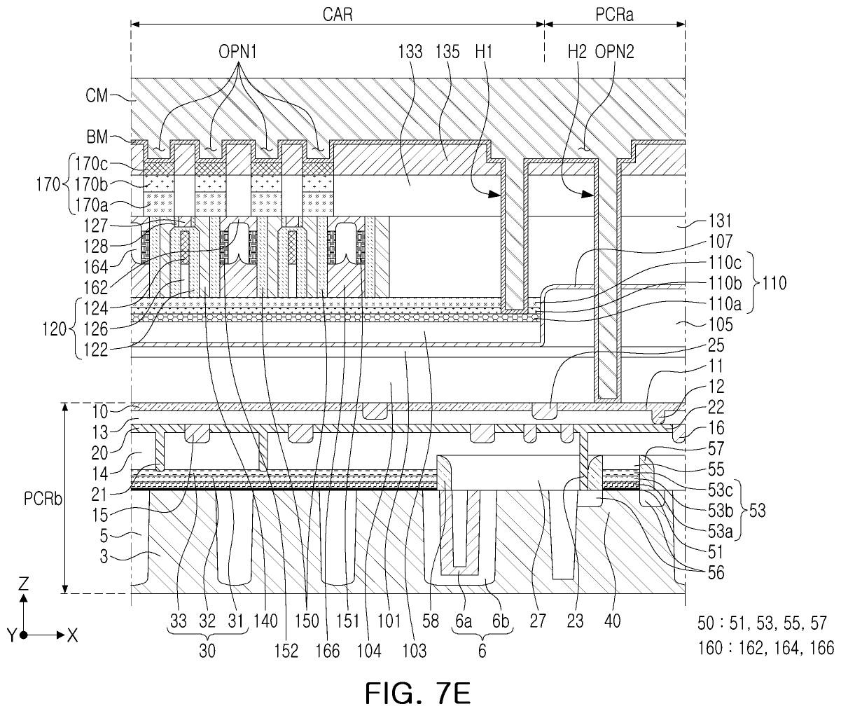

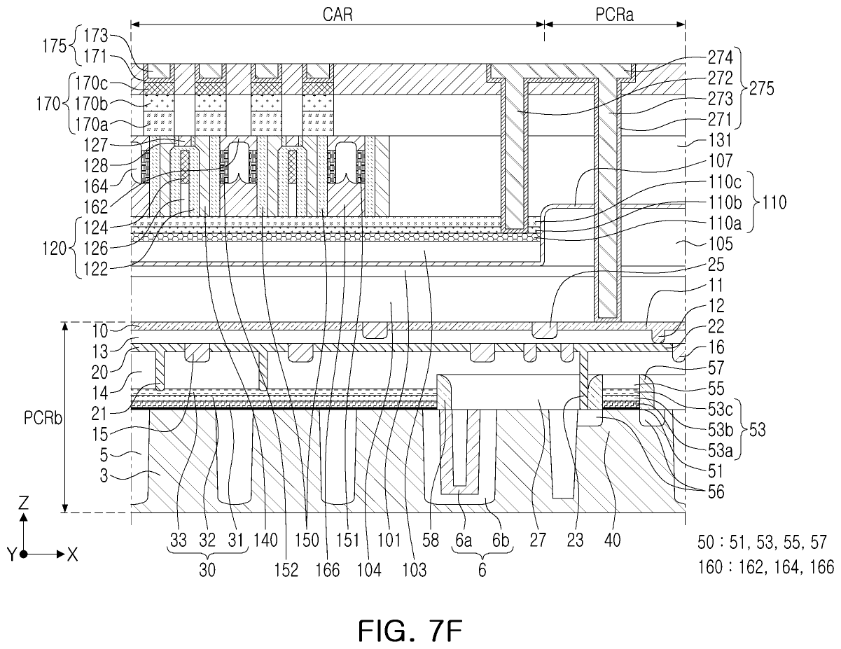

FIGS. 7A to 7F are schematic cross-sectional views illustrating an example embodiment of intermediate processes in a method of manufacturing a semiconductor device.

Referring to FIG. 7A, after forming seventh and eighth interlayer insulating layers 133 and 135 on the channel layers 140, first openings OPN1 penetrating in the vertical direction (Z-direction) through the seventh and eighth interlayer insulating layers 133 and 135 may be formed so that the upper surfaces of the channel layers 140 are exposed. The term “exposed” (or “exposes,” or like terms) may be used herein to describe relationships between elements and/or with reference to intermediate processes in fabricating a semiconductor device, but may not require exposure of a particular element in the completed device. Likewise, the term “not exposed” may be used to described relationships between elements and/or with reference to intermediate processes in fabricating a semiconductor device, but may not require a particular element to be unexposed in the completed device. First contact patterns 170 may be formed on the channel layers 140 exposed through the first openings OPN1. The first contact patterns 170 may at least partially fill the first openings OPN1 penetrating through the seventh interlayer insulating layer 133, and portions of the first contact patterns 170 may be formed in the first openings OPN1 formed in the eighth interlayer insulating layer 135. The term “fill” (or “fills,” or like terms) is intended to refer to either completely filling a defined space (e.g., the first openings OPN1) or partially filling the defined space; that is, the defined space need not be entirely filled but may, for example, be partially filled or have voids or other spaces throughout. An upper surface of the third contact layer 170c of the first contact patterns 170 may be exposed through the first openings OPN1 formed in the eighth interlayer insulating layer 135.

Referring to FIG. 7B, a sacrificial layer SL may be formed on the eighth interlayer insulating layer 135 to fill the remaining portion of the first openings OPN1 and extend onto an upper surface of the eighth interlayer insulating layer 135. The sacrificial layer SL may be formed through a spin-on coating process. The sacrificial layer SL may include a carbon-containing material. In an example, the sacrificial layer SL may be a spin-on carbon layer.

After forming the sacrificial layer SL, a first through-hole H1 is formed sequentially penetrating in the vertical direction through the sacrificial layer SL and the sixth, seventh and eighth interlayer insulating layers 131, 133 and 135 to expose an upper surface of the bit line structure 110, and a second through-hole H2 is formed sequentially penetrating in the vertical direction through the sacrificial layer SL, the sixth, seventh and eighth interlayer insulating layers 131, 133 and 135, the insulating liner 107, the fifth separation insulating pattern 105, the fourth interlayer insulating layer 101 and the third interlayer insulating layer 104 to expose an upper surface of the fourth peripheral interconnection line 11 of the fourth peripheral interconnection structures 11 and 12.

Referring to FIG. 7C, a portion of the eighth interlayer insulating layer 135 may be removed to form a second opening OPN2 overlapping the first and second through-holes H1 and H2 in the vertical direction. The eighth interlayer insulating layer 135 may be etched using the sacrificial layer SL as an etching mask. Accordingly, the second opening OPN2 corresponding to a trench may be formed. The second opening OPN2 is a trench connected to the first and second through-holes H1 and H2, and may be a via-first dual damascene opening in which the first and second through-holes H1 and H2 are first defined (or formed) and then the trench is formed.

Referring to FIG. 7D, the sacrificial layer SL may be removed. The sacrificial layer SL may be removed through a photoresist strip process. For example, the sacrificial layer SL may be removed by oxygen ashing. Subsequently, a cleaning process may be performed to remove etching by-products, or the like. As the sacrificial layer SL is removed, upper surfaces of the first contact patterns 170 may be exposed through the first openings OPN1, the upper surface of the bit line structure 110 and the upper surface of the fourth peripheral interconnection line 11 may be exposed through the first and second through-holes H1 and H2 and the second opening OPN2.

Referring to FIG. 7E, a barrier film BM and a conductive film CM may be sequentially formed to cover the first openings OPN1 formed on the eighth interlayer insulating layer 135, the first and second through-holes H1 and H2, and the second opening OPN2. The barrier film BM may be formed in the first openings OPN1, the first and second through-holes H1 and H2 and the second opening OPN2. The barrier film BM may be formed by a deposition process such as an atomic layer deposition process. The barrier film BM may conformally cover side surfaces and bottom surfaces of the first openings OPN1, side surfaces and bottom surfaces of the first and second through-holes H1 and H2, and a side surface and a bottom surface of the second opening OPN2 extending from the first and second through-holes H1 and H2. The term “conformal” (or “conformally,” or like terms), as may be used herein in the context of a material layer or coating, is intended to refer broadly to a material layer or coating having a substantially uniform cross-sectional thickness relative to the contour of a surface to which the material layer is applied. The conductive film CM may fill the first openings OPN1, the first and second through-holes H1 and H2 and the second opening OPN2 covered with the barrier film BM.

Referring to FIG. 7F, a planarization process may be performed on the barrier film BM and the conductive film CM so as to expose the upper surface of the eighth interlayer insulating layer 135. The planarization process may include an etch back or a chemical mechanical polishing (CMP) process. Through the planarization process, second contact patterns 175 including a first contact pattern barrier layer 171 and a first conductive pattern 173, and a contact structure 275 including a first contact plug portion 272, a second contact plug portion 273, a connection portion 274 and a contact barrier layer 271 may be formed.

Referring to FIG. 3 and FIG. 7F, the first etching stop layer 136, the information storage structure 180, and the upper insulating film 137 may be sequentially formed on the second contact patterns 175. Accordingly, the semiconductor device 100 of FIG. 1 to FIG. 3 may be manufactured.

While example embodiments have been shown and described above, it will be apparent to those skilled in the art that modifications and variations could be made without departing from the scope of the present disclosure as defined by the appended claims.

What is claimed is:

1. A semiconductor device, comprising:
a bit line structure;
cell channel structures on the bit line structure and respectively extending in a vertical direction perpendicular to a surface of the semiconductor device;
word lines between the cell channel structures;
first contact patterns on the cell channel structures and electrically connected to the cell channel structures;
second contact patterns on the first contact patterns;
an information storage structure on the second contact patterns;
a peripheral transistor including a peripheral gate electrode and a peripheral source/drain;
a peripheral conductive interconnection on the peripheral transistor and electrically connected to the peripheral transistor; and
a contact structure including a first contact plug portion connected to the bit line structure, a second contact plug portion horizontally spaced apart from the first contact plug portion and electrically connected to the peripheral conductive interconnection, and a connection portion extending from the first contact plug portion and the second contact plug portion,
wherein the contact structure includes a contact conductive pattern in the connection portion and extending from a portion in the connection portion into the first contact plug portion and the second contact plug portion,
each of the second contact patterns includes a same material as a material of the contact conductive pattern, and
upper surfaces of each of the second contact patterns are coplanar with an upper surface of the connection portion of the contact structure, relative to the surface of the semiconductor device.

2. The semiconductor device of claim 1,
wherein each of the second contact patterns includes a first conductive pattern and a contact pattern barrier layer on a side surface and a bottom surface of the first conductive pattern, and
the contact structure further includes a contact barrier layer on a side surface and a lower surface of the first contact plug, a side surface and a lower surface of the second contact plug, and a side surface and a lower surface of the connection portion.

3. The semiconductor device of claim 2,
wherein a length from a lower surface to an upper surface of the first conductive pattern of each of the second contact patterns is greater than a length from the lower surface to an upper surface of the connection portion.

4. The semiconductor device of claim 2,
wherein each of the first conductive pattern and the contact conductive pattern includes tungsten (W), and
the contact pattern barrier layer and the contact barrier layer include a same metallic material.

5. The semiconductor device of claim 1, further comprising
an interlayer insulating layer extending around side surfaces of the second contact patterns, a side surface of the connection portion, an upper end portion of the first contact plug portion, and an upper end portion of the second contact plug,
wherein an upper surface of the interlayer insulating layer is coplanar with the upper surfaces of each of the second contact patterns and the upper surface of the connection portion of the contact structure, relative to the surface of the semiconductor device.

6. The semiconductor device of claim 5,
wherein, in the vertical direction, a lower surface of the interlayer insulating layer is on a level lower than a level of lower surfaces of the second contact patterns and a lower surface of the connection portion.

7. The semiconductor device of claim 1,
wherein, in the vertical direction, a lower surface of the first contact plug is on a level higher than a level of a lower surface of the second contact plug, relative to the surface of the semiconductor device.

8. The semiconductor device of claim 1,
wherein the peripheral conductive interconnection line is on a level lower than a level of the bit line structure, relative to the surface of the semiconductor device.

9. The semiconductor device of claim 1,
wherein the information storage structure includes first electrodes electrically connected to the second contact patterns, a second electrode on the first electrodes, and a dielectric layer between the first electrodes and the second electrode,
wherein lower surfaces of each of the first electrodes are coplanar with the upper surfaces of each of the second contact patterns and the upper surface of the connection portion of the contact structure, relative to the surface of the semiconductor device.

10. The semiconductor device of claim 9, further comprising:
an insulating liner on the second contact patterns and the connection portion of the contact structure,
wherein the first electrodes are electrically connected to the second contact patterns by penetrating through the insulating liner.

11. The semiconductor device of claim 1,
wherein the first contact plug and the second contact plug overlap the connection portion in the vertical direction.

12. A semiconductor device, comprising:
a bit line structure;
cell channel structures on the bit line structure and respectively extending in a vertical direction perpendicular to a surface of the semiconductor device;
word lines between the cell channel structures;
first contact patterns on the cell channel structures and electrically connected to the cell channel structures;
second contact patterns on the first contact patterns;
an information storage structure on the second contact patterns; and
a first contact structure including a first contact plug connected to the bit line structure, a first connection portion having a width, in a horizontal direction parallel to the surface of the semiconductor device and perpendicular to the vertical direction, greater than a width, in the horizontal direction, of the first contact plug on the first contact plug, and a first contact barrier layer on a side surface and a lower surface of the first contact plug, and a side surface and a lower surface of the first connection portion,
wherein upper surfaces of each of the second contact patterns are coplanar with an upper surface of the first contact structure, relative to the surface of the semiconductor device.

13. The semiconductor device of claim 12,
wherein each of the second contact patterns includes a first conductive pattern and a conductive pattern barrier layer on a side surface and a bottom surface of the first conductive pattern.

14. The semiconductor device of claim 12, further comprising:
a peripheral transistor including a peripheral gate electrode and a peripheral source/drain;
a peripheral conductive interconnection line on the peripheral transistor and electrically connected to the peripheral transistor; and
a second contact structure including a second contact plug electrically connected to the peripheral conductive interconnection line, a second connection portion on the second contact plug, the second connection portion having a width in the horizontal direction greater than a width in the horizontal direction of the second contact plug, and a second contact barrier layer extending from a side surface of the second contact plug and a side surface of the second contact plug to cover a side surface and a lower surface of the second connection portion,
wherein an upper surface of the second connection portion of the second contact structure is coplanar with an upper surface of the first connection portion of the first contact structure, relative to the surface of the semiconductor device.

15. The semiconductor device of claim 14,
wherein the first contact structure and the second contact structure are spaced apart from each other in the horizontal direction.

16. The semiconductor device of claim 14, further comprising:
a separation insulating pattern extending around a side surface of the bit line structure,
wherein the second contact structure is electrically connected to the peripheral conductive interconnection line below the separation insulating pattern by penetrating through the separation insulating pattern.

17. The semiconductor device of claim 14,
wherein a distance from a lower surface to an upper surface of the first connection portion of the first contact structure in the vertical direction is equal to a distance from a lower surface to an upper surface of the second connection portion of the second contact structure in the vertical direction.

18. The semiconductor device of claim 14,
wherein the first contact plug of the first contact structure and the second contact plug of the second contact structure are spaced apart from each other in the horizontal direction, and
the first connection portion of the first contact structure and the second connection portion of the second contact structure are formed integrally with each other.

19. A semiconductor device, comprising:
a bit line structure;
cell channel structures on the bit line structure and respectively extending in a vertical direction perpendicular to a surface of the semiconductor device;
word lines between the cell channel structures;
first contact patterns on the cell channel structures and electrically connected to the cell channel structures;
second contact patterns including conductive patterns on the first contact patterns and contact pattern barrier layers on side surfaces and lower surfaces of the conductive patterns;
an information storage structure on the second contact patterns;
a peripheral transistor including a peripheral gate electrode and a peripheral source/drain;
a peripheral conductive interconnection line on the peripheral transistor and electrically connected to the peripheral transistor; and
a contact structure including a first contact plug portion electrically connected to the bit line structure, a second contact plug portion electrically connected to the peripheral conductive interconnection line, a connection portion extending from the first contact plug portion and the second contact plug portion, and a contact barrier layer on a side surface and a lower surface of the first contact plug portion, a side surface and a lower surface of the second contact plug, and a side surface and a lower surface of the connection portion.

20. The semiconductor device of claim 19, further comprising:
an interlayer insulating layer extending around side surfaces of the second contact patterns, the side surface of the connection portion, an upper end portion of the first contact plug portion, and an upper end portion of the second contact plug,
wherein a lower surface of the interlayer insulating layer is on a level lower than a level of lower surfaces of the second contact patterns and the lower surface of the connection portion, relative to the surface of the semiconductor device.
